(19) United States
(12) Patent Application Publication
(10) Pub. No.: US 2013/0136949 A1
(43) Pub. Date: May 30, 2013

(54) ALUMINUM ALLOY FILM, WIRING STRUCTURE HAVING ALUMINUM ALLOY FILM, AND SPUTTERING TARGET USED IN PRODUCING ALUMINUM ALLOY FILM

(71) Applicants: Hiroyuki Okuno, Kobe-shi (JP); Toshihiro Kugimiya, Kobe-shi (JP)

(72) Inventors: Hiroyuki Okuno, Kobe-shi (JP); Toshihiro Kugimiya, Kobe-shi (JP)

(73) Assignee: Kabushiki Kaisha Kobe Seiko Sho (Kobe Steel, Ltd.), Kobe-shi, Hyogo (JP)

(21) Appl. No.: 13/813,816

(22) PCT Filed: Sep. 26, 2011
(86) PCT No.: PCT/JP2011/071912

§ 371 Date: Feb. 1, 2013

(30) Foreign Application Priority Data
Sep. 30, 2010 (JP) 2010-222005
Jun. 7, 2011 (JP) 2011-127711

(51) Int. Cl. H05K 1/02; C22C 21/00; C23C 14/34

(52) U.S. Cl. CPC H05K 1/0298; C23C 14/3414; C22C 21/00
USPC 428/622; 428/457; 428/469; 428/336; 204/298.13; 420/552

(57) ABSTRACT

The present invention provides an Al alloy film that, in a production step of a thin-film transistor substrate, reflective film, reflective anode, touch panel sensor, or the like, can effectively prevent corrosion such as pinhole corrosion (black dots) or corrosion of the Al alloy surface when immersed in a sodium chloride solution, has superior corrosion resistance, is able to suppress hillock formation, and has superior heat resistance. The Al alloy thin film is used as a reflective film or a wiring film on a substrate, and contains 0.01-0.5 at % of Ta and/or Ti and 0.05-2.0 at % of a rare earth element.

### TECHNICAL FIELD

The present invention relates to an Al alloy film suitable for use in reflective films and wiring films (including electrodes) for display devices and touch panel sensors, a wiring structure having the Al alloy film, a sputtering target used in producing the Al alloy film, and a thin film transistor, a reflective film, a reflective anode for organic EL, and a touch panel sensor each including the Al alloy film. In particular, the present invention relates to an Al alloy film that has excellent corrosion resistance such as corrosion resistance in sodium chloride solution and resistance to transparent conductive film pinhole corrosion, and excellent heat resistance. In the description below, Al alloy films used in wiring films of thin film transistors and liquid crystal display devices are mainly described; however, the usage of the Al alloy film of the present invention is not limited to these usages.

### BACKGROUND ART

Liquid crystal display devices (LCDs) used in various fields ranging from small cellular phones to over 30-inch large televisions use thin film transistors (TFTs) as switching device and are each constituted by a TFT substrate that includes transparent pixel electrodes, electrode wiring units such as gate wiring and source-drain wiring, and semiconductor layers, a counter substrate that includes a common electrode and is arranged to oppose the TFT substrate with a particular gap therebetween, and a liquid crystal layer filling the space between the TFT substrate and the counter substrate.

Pure Al films or Al alloy films such as Al—Nd (hereinafter, the pure Al films and the Al alloy films may be generally referred to as “Al films”) are widely used as the electrode wiring material for use in source-drain wiring since they have low electrical resistance and easily allow microfabrication, for example. The Al films are connected to transparent conductive films that constitute transparent pixel electrodes through barrier metal layers usually composed of Ti or Mo.

There has been a proposal regarding the TFT substrate, in which an Al alloy film that has low contact resistance even when directly connected to a transparent conductive film (e.g., ITO film or IZO film) constituting a transparent pixel electrode without using barrier metal layers is used in the wiring (for example, refer to PTL 1).

Display devices in an actual operating environment are sometimes exposed to a humid environment and wiring films may become corroded in such a case. This corrosion occurs not only due to the direct contact between moisture such as water vapor in the environment and the wiring films. The corrosion also occurs when moisture such as water vapor penetrates gaps, such as pinholes and cracks, in a resin or silicon-based insulating film or transparent conductive film and reaches the surface of the wiring film.

An issue relating to the corrosion in such a humid environment that has recently been raised is pinhole corrosion caused by ITO film coating on TFTs. The pinhole corrosion is considered to be caused by water vapor that has penetrated pinholes in ITO films serving as transparent conductive films and reached the interfaces between the ITO films and Al films, thereby causing galvanic corrosion.

In the past, production of liquid crystal display devices such as one shown in FIG. 1 of PTL 1 has been completed in the same one plant. However, with recent trends of dividing the process, there are an increasing number of cases where a process up to formation of a transparent conductive film 5 (e.g., indium tin oxide (ITO) film) shown in FIG. 2 of PTL 1 is carried out in one plant and the subsequent process is carried out in another plant. In such cases, during storage or transportation to another plant, water vapor penetrates pinholes (non-continuous portions in transparent conductive films) in transparent conductive films, galvanic corrosion (hereinafter may be referred to as “pinhole corrosion”) occurs due to a potential difference between the transparent conductive films and the Al films constituting the source-drain wiring, and the corroded parts are sometimes identified as black dots. When black dots occur, it becomes difficult to produce display devices having high reliability.

The source-drain wires are connected to driver ICs by press-bonding with anisotropic conductive films (ACE) interposed therebetween (such portions are referred to as TAB portions). The same problems as those described above may arise in the TAB portions.

These problems also arise in the above-described TFT substrate that has a structure in which a transparent conductive film constituting transparent pixel electrodes is connected to an Al film through a barrier metal layer composed of Ti or Mo. When a dry etching process is excessively carried out, ITO/Al structures may be formed in some parts (such as contact holes) and pinhole corrosion may occur.

In order to address the issue of pinhole corrosion caused by ITO film coatings, various methods for preventing the corrosion have been proposed. For example, PTL 2 describes that a coating solution containing a film-forming agent and an ion exchange material is applied to a surface of an oxide semiconductor such as ITO constituting a transparent conductive film of a display device. PTL 3 describes that a coating solution having a water-repelling property is applied to a surface of an oxide semiconductor. According to PTL 2 and PTL 3, corrosion caused by water vapor is prevented by applying a coating solution to the surfaces of oxide semiconductors.

### CITATION LIST

### Patent Literature

PTL 1: Japanese Unexamined Patent Application Publication No. 2009-105424
PTL 2: Japanese Unexamined Patent Application Publication No. 11-286628
PTL 3: Japanese Unexamined Patent Application Publication No. 11-323205

### SUMMARY OF INVENTION

### Technical Problem

When techniques described in PTL 2 and PTL 3 are used, a process of applying the coating solution to surfaces of oxide semiconductors (transparent conductive films) is required before transportation and the films formed by application and the coating solution must be removed before the next process is carried out in the separate plant after transportation and storage, resulting in low production efficiency.

In the description above, pinhole corrosion caused by ITO film coating of the thin film transistors is described as an example. However, such an issue of corrosion occurs regardless of the presence or absence of the ITO film coatings. For example, there is another problem in that the Al alloy surface will corrode when exposed and immersed in a sodium chloride solution.

Yet another problem is that when Al films are used as electrode wiring films without using barrier metal layers, lump-like protrusions called hillocks are formed on the surfaces of the Al films since Al is easily oxidizable and the display quality of the screen will be degraded.

As discussed above, various types of corrosion phenomena occur in display devices regardless of the types of the display devices. In particular, for example, corrosion occurs similarly in wiring films (including electrodes), reflective films, and reflective anodes of display devices such as liquid crystal display devices, organic EL devices, and touch panel sensors. Accordingly, there is a high anticipation for the technique that can effectively prevent these types of corrosion, in particular, a technique that can effectively prevent corrosion of Al alloy films used in wiring films for thin film transistors (e.g., corrosion of Al alloy surfaces exposed and immersed in sodium chloride solution) and pinhole corrosion caused by ITO film coatings of TFTs.

The present invention has been made under the above-described circumstances. An object thereof is to provide a technology for enhancing heat resistance, preventing generation of hillocks, and enhancing corrosion resistance by effectively preventing corrosion such as pinhole corrosion (black dots) and corrosion of Al alloy surfaces immersed in sodium chloride solutions, for example, without requiring a step of applying and removing corrosion-preventing coating solutions in the processes of producing thin film transistor substrates, reflective films, reflective anodes, and touch panel sensors.

### Solution to Problem

The present invention provides the following Al alloy films, wiring structure, thin film transistor, reflective film, reflective anode for organic EL, touch panel sensor, display device, and sputtering target.

(1) An Al alloy film for use in a wiring film or a reflective film, containing 0.01 to 0.5 at. % of Ta and/or Ti and 0.05 to 2.0 at. % of a rare earth element.

(2) The Al alloy film according to (1), in which the rare earth element is at least one element selected from the group consisting of Nd, La, and Gd.

(3) The Al alloy film according to (1) or (2), in which, when the Al alloy film is immersed in a 1% aqueous sodium chloride solution at 25° C. for 2 hours and a surface of the Al alloy film is observed with an optical microscope at a magnification of 1000, the fraction of a corroded area in the Al alloy film surface relative to the total area of the Al alloy film surface is suppressed to 10% or less.

(4) A wiring structure that includes a substrate, the Al alloy film according to (1) or (2), and a transparent conductive film, in which, from the substrate side, the Al alloy film and the transparent conductive film are formed in that order, or the transparent conductive film and the Al alloy film are formed in that order.

(5) The wiring structure according to (4), in which the Al alloy film is directly connected to the transparent conductive film.

(6) The wiring structure according to (4), in which the Al alloy film and the transparent conductive film are formed in that order from the substrate side, and in which, when an Al-transparent conductive film multilayer sample in which the transparent conductive film is formed on a part of the Al alloy film either directly or with a refractory metal film therebetween is immersed in a 1% aqueous sodium chloride solution at 25° C. for 2 hours and an Al alloy film surface on which the transparent conductive film is not formed is observed with an optical microscope at a magnification of 1000, the fraction of a corroded area in the Al alloy film surface relative to the total area of the Al alloy film surface on which the transparent conductive film is not formed is suppressed to 10% or less.

(7) The wiring structure according to (4), in which the transparent conductive film and the Al alloy film are formed in that order from the substrate side, and in which, when a transparent conductive film-Al multilayer sample in which the Al alloy film is formed on the transparent conductive film either directly or with a refractory metal film therebetween or in which the Al alloy film is formed on the transparent conductive film and a refractory metal film is formed on a part of the Al alloy film is immersed in a 1% aqueous sodium chloride solution at 25° C. for 2 hours and a surface of the Al alloy film is observed with an optical microscope at a magnification of 1000, the fraction of a corroded area in the Al alloy film surface relative to the total area of the Al alloy film surface is suppressed to 10% or less.

(8) The wiring structure according to (4), in which the Al alloy film and the transparent conductive film are formed in that order from the substrate side, and in which, when an Al-transparent conductive film multilayer sample in which the transparent conductive film is directly formed on the Al alloy film is exposed to a humid environment at 60° C. and a relative humidity of 90% for 500 hours, a density of pinhole corrosion formed through pinholes in the transparent conductive film is 40 pinholes/mm² or less in an area with optical microscope at a magnification of 1000.

(9) The wiring structure according to any one of (4) to (8), in which the transparent conductive film is composed of ITO or IZO.

(10) The wiring structure according to any one of (4) to (9), wherein the thickness of the transparent conductive film is 20 to 120 nm.

(11) A thin film transistor including the wiring structure according to any one of (4) to (10).

(12) A reflective film including the wiring structure according to any one of (4) to (10).

(13) A reflective anode for organic EL, including the wiring structure according to any one of (4) to (10).

(14) A touch panel sensor including the Al alloy film according to any one of (1) to (3).

(15) A display device including the thin film transistor according to (11).

(16) A display device including the reflective film according to (12).

(17) A display device including the reflective anode for organic EL according to (13).

(18) A display device comprising the touch panel sensor according to (14).

(19) A sputtering target for use in producing a wiring film or a reflective film for a display device or a wiring film for a touch panel sensor, the sputtering target containing 0.01 to 0.5 at. % of Ta and/or Ti and 0.05 to 2.0 at. % of a rare earth element, the balance being Al and unavoidable impurities.

(20) The sputtering target according to (19), wherein the rare earth element is at least one element selected from the group consisting of Nd, La, and Gd.

### Advantageous Effects of Invention

According to the present invention, a high-performance Al alloy film that has excellent heat resistance and excellent corrosion resistance so that corrosion does not occur even when the step of applying and separating an anti-corrosion coating solution is not provided unlike in the related art, and a wiring structure, a thin film transistor, a reflective film, a reflective anode for organic EL, a touch panel sensor, and a display device each including the Al alloy film can be produced at a low cost. A sputtering target of the present invention is suitable for use in production of the Al alloy film.

### BRIEF DESCRIPTION OF DRAWINGS

FIG. 1 is a diagram showing a configuration of an organic EL display device that includes a reflective anode.

FIG. 2 is a diagram showing a configuration of a display device that includes a thin film transistor.

FIG. 3 is a diagram showing a configuration of a display device that includes a reflective film (an Al alloy reflective film on an ITO film).

FIG. 4 is a diagram showing a configuration of a display device that includes a reflective film (an ITO film on an Al alloy reflective film).

FIG. 5 Parts (a) and (b) of FIG. 5 are each a diagram showing a configuration of a touch panel that includes an Al alloy wiring film on an ITO film, part (a) of FIG. 5 showing barrier metal films disposed on and under an Al alloy wiring film, part (b) of FIG. 5 showing a barrier metal film under an Al alloy wiring film.

### DESCRIPTION OF EMBODIMENTS

The inventors of the present invention have conducted extensive researches to realize an Al alloy film that has excellent corrosion resistance, namely, an Al alloy film with which corrosion of the surface immersed in a sodium chloride solution is suppressed and corrosion (black dots) caused by pinholes in a transparent conductive film in a humid environment is suppressed, and excellent heat resistance.

As a result, they have found that when an Al alloy film that contains particular amounts of Ta and/or Ti and a rare earth element is used, corrosion of the Al alloy surface immersed in a sodium chloride solution can be suppressed, formation of pinholes can be effectively prevented so that the density of the pinhole corrosion can be reduced, and generation of hillocks can be suppressed, and made the present invention.

The feature of the present invention is thus that an Al alloy film containing particular amounts of Ta and/or Ti and a rare earth element is used as an Al alloy film that has excellent hillock prevention (heat resistance) as well as excellent corrosion resistance (in particular, resistance to corrosion in sodium chloride solution and resistance to ITO pinhole corrosion (ITO pinhole corrosion density reducing effect)).

Of these, Ta and/or Ti is an element that contributes to improving the corrosion resistance and has excellent effects of improving the corrosion resistance in sodium chloride solution and decreasing the density of ITO pinhole corrosion as described in Examples below. In the present invention, Ta and Ti may be used alone or in combination. In order to effectively realize the above-describe effects, the content thereof (when Ta and Ti are contained alone, it is the content of one element and when contained in combination, it is the total content of the two elements) is set to 0.01 at. % or more. The higher the content, the more notable the effects. Preferably, the content is 0.1 at. % or more and more preferably 0.15 at. % or more. However, when the content is excessively high, the corrosion resistance improving effect becomes saturated and the electrical resistance of wiring will increase. Thus, the upper limit of the content is set to 0.5 at. % and more preferably 0.3 at. %.

The rare earth element is an element particularly effective for preventing occurrence of hillocks. The rare earth element used in the present invention is one or more selected from the element group consisting of lanthanoid elements (in the periodic table, 15 elements from La having an atomic number of 57 to Lu having an atomic number of 71), scandium (Sc), and yttrium (Y). Preferred rare earth elements are Nd, La, and Gd, which may be used alone or in combination. In order to effectively yield the above-described effects, the rare earth element content (when one rare earth element is contained, it is the content of that one element and when two or more rare earth elements are contained, it is the total content of the two or more elements) is set to 0.05 at. % or more. The higher the rare earth element content, the more notable the effects. Thus, the preferable rare earth element content is 0.1 at. % or more, more preferably 0.15 at. % or more, yet more preferably 0.25 at. % or more, and most preferably 0.28 at. % or more. However, when the rare earth element content is excessively high, the above-described effects become saturated and the electrical resistance of wiring will increase. Thus, the upper limit of the content is set to 2.0 at. %, preferably 1.0 at. %, and more preferably 0.6 at. %.

The Al alloy film may contain elements other than those described above so that other properties are imparted on the assumption that the effects of the present invention described above are effectively exhibited.

The Al alloy film used in the present invention contains above-described components and the balance being Al and unavoidable impurities. Examples of the unavoidable impurities include Fe, Si, and B. The total content of the unavoidable impurities is not particularly limited but may typically be 0.5 at. % or less. As for individual unavoidable impurities, the B content may be 0.012 at. % or less and Fe and Si contents may each be 0.12 at. % or less.

The present invention includes a wiring structure having the Al alloy film described above and a transparent conductive film. In particular, examples of the wiring structure of the present invention include both a structure in which the Al alloy film and the transparent conductive film are formed in that order from the substrate side and a structure in which the transparent conductive and the Al alloy film are formed in that order from the substrate side.

The most distinctive feature of the present invention is that the composition of the Al alloy film is specified. The requirements other than those related to the Al alloy film (other requirements related to transparent conductive films, barrier metal films described below, and other TFT substrates and display devices) are not particularly limited and those usually used in the field can be employed. For example, representative examples of the transparent conductive films include ITO films and IZO films.

The thickness of the transparent conductive film is preferably 20 to 120 nm. When the film thickness is less than 20 nm, problems such as disconnections and an increase in electrical resistance may occur. At a film thickness exceeding 120 nm, a problem such as a decrease in transmittance may occur. A more preferable thickness range of the transparent conductive film is 40 to 100 nm. The thickness of the Al alloy film is preferably about 100 to 800 nm.

In the wiring structure of the present invention, the Al alloy film and the transparent conductive film may be directly connected to each other or a known barrier metal film may be included in the wiring structure. The type (composition) of the barrier metal film is not particularly limited as long as it is of a type that is usually employed in display devices and may be appropriately selected within the range that does not impair the effects of the present invention. For example, metal wiring films composed of refractory metals such as Ti and Mo and alloys containing refractory metals can be used as the barrier metal film. Moreover, the location of the barrier metal film is not particularly limited and, for example, the barrier metal film may be interposed between the Al alloy film and the transparent conductive film or may be disposed on the Al alloy film.

The Al alloy film and the wiring structure that includes the Al alloy film according to the present invention have exceptionally high corrosion resistance. As discussed above, while the Al alloy film of the present invention can be used in various types of devices such as display devices, excellent corrosion resistance is exhibited irrespective of the state in which the Al alloy film is arranged in those devices (that is, regardless of the existing form of the Al alloy film, for example, the Al alloy film may be a single layer; a transparent conductive film may be directly connected to a part of an Al alloy film; a transparent conductive film may be connected to a part of an Al alloy film with a refractory metal film therebetween; an Al alloy film alone may be formed directly on a transparent conductive film; an Al alloy film may be formed on a transparent conductive film with a refractory metal therebetween; or an Al alloy film may be formed on a transparent conductive film and a refractory metal film may be formed on a part of the Al alloy film).

To be more specific, when a corrosion test of immersing a sample in a 1% aqueous sodium chloride solution at 25° C. for 2 hours is conducted as the corrosion test for evaluating corrosion resistance in sodium chloride solution, and the sample of the Al alloy film after corrosion test is observed with a ×1000 optical microscope, the fraction of the corroded area of the Al alloy film surface is suppressed to 10% or less relative to the total area of the Al alloy film. This is an indicator used when the sample is an Al alloy film single layer. However, this can be used as an indicator in the case where an Al (lower layer)-transparent conductive film (upper layer) multilayer sample in which the transparent conductive film is directly formed on a part of the Al alloy film is used and in the case where an Al (lower layer)-refractory metal film (middle layer)-transparent conductive film (upper layer) multilayer sample in which the transparent conductive film is formed on a part of the Al alloy film with a refractory metal film therebetween is used (details of the method for preparing multilayer samples are given in Examples below). In such multilayer samples, corrosion phenomena occur on Al alloy film surfaces that do not have transparent conductive films thereon. However, according to the present invention, the fraction of the corroded area of the Al alloy film on which no transparent conductive film is formed is suppressed to 10% or less relative to the total area of the Al alloy film. Moreover, this indicator can be used as an indicator for multilayer samples in which the order of stacking the Al alloy film and the transparent conductive film is reversed compared to the above-described multilayer samples. That is, this indicator can be used as an indicator for a transparent conductive film (lower layer)-Al (upper layer) multilayer sample in which the Al alloy film alone is formed directly on the transparent conductive film, for a transparent conductive film (lower layer)-refractory metal film (middle layer)-Al (upper layer) multilayer sample in which the refractory metal film and the Al alloy film are sequentially formed on the transparent conductive film, and for a transparent conductive film (lower layer)-Al (middle layer)-refractory metal film (upper layer) multilayer sample in which the Al alloy film is formed on the transparent conductive film and the refractory metal film is formed on a part of the Al alloy film (details of the method for preparing multilayer samples are given in Examples below). The fraction of the corroded area of the Al alloy film located at the outermost surface or under the refractory metal is suppressed to 10% or less relative to the total area of the Al alloy film in any of these samples. In any structure, the corroded area of the Al alloy film is preferably as small as possible, more preferably 8% or less, and most preferably 5% or less.

When the ITO pinhole corrosion resistance (ITO pinhole corrosion density reducing effect) is evaluated through a corrosion test of exposing an Al (lower layer)-transparent conductive film (upper layer) multilayer sample, in which the transparent conductive film is directly stacked on the Al alloy film, to a 60° C., 90% humidity environment for 500 hours, the pinhole corrosion density after the corrosion test is suppressed to 40 pinholes/mm² or less (average of 10 areas of observation arbitrarily selected) in ×1000 optical microscope areas of observation (10 areas of observation arbitrarily selected). This corrosion test is selected by considering the difficulty of directly observing the density of pinholes in the transparent conductive film and the pinhole size (diameter). Thus, the density and size of pinholes are observed with a TEM by inducing pinhole corrosion of an electrode wiring film (base Al film) through pinholes in the transparent conductive film so that the pinholes become visible. The pinhole corrosion density is more preferably 20 pinholes/mm² or less and yet more preferably 10 pinholes/mm² or less. Pinhole corrosion can also occur in a substrate used in a TAB portion. Thus, the TFT substrate of the present invention exhibits the same effects even in the cases where the substrate is used in the TAB portion of a display device.

In the present invention, basically, a wiring structure in which a transparent conductive film (for example, an ITO film) and an electrode wiring film constituted by an Al alloy film are in direct contact with each other can be formed by sequentially performing steps (a) to (d) below. The conditions employed in each step may be any common conditions unless otherwise noted. The processes that are performed in association with these steps may also be performed under common conditions:

(a) a step of forming an Al alloy film having the above-described composition on a substrate surface by a sputtering method or the like;
(b) a step of performing a heat treatment that simulates the heat history by CVD process of forming an insulating layer such as a silicon nitride (SiN) film on the Al alloy film;
(c) a step of forming a transparent conductive film (e.g., ITO film); and
(d) a step of performing a heat treatment to crystallize the transparent conductive film (e.g., ITO film).

In (c) of these steps, the thickness of the ITO film is preferably large to ensure higher resistance to transparent conductive film pinhole corrosion. In order to do so, the ITO film is to be formed by a sputtering method as described above and the film deposition power and the substrate temperature are preferably increased during the ITO film formation. This is because, while an ITO film formed by using a sputtering target grows to have a stripe pattern when viewed from a cross-section, the thickness of the ITO film can be increased by appropriately controlling the sputtering conditions during deposition. In particular, the film deposition power is preferably about 200 W/4 inch or more (more preferably 300 W/4 inch or more) and the substrate temperature during the film deposition is preferably 50° C. or more, more preferably 100° C. or more, and yet more preferably 150° C. or more. Although the upper limits thereof are not particularly limited, the upper limit of the substrate temperature during film deposition is 200° C. considering the crystallization of the ITO film.

In (d), the heat treatment conditions preferred for crystallizing the ITO film are, for example, 200 to 250° C. in a nitrogen atmosphere for 10 minutes or more.

After (a) to (d) above, typical steps for producing display devices are performed to produce a TFT substrate. In particular, refer to the production steps described in PTL 1 described above.

The description above is the example of forming an Al (lower layer)-transparent conductive film (upper layer) wiring structure. In order to make a transparent conductive film (lower layer)-Al (upper layer) wiring structure, the following steps may be sequentially conducted. The conditions of the steps (a′) to (d′) etc., are the same as those of steps (a) to (d) above.

(c′) a step of forming a transparent conductive film (e.g., ITO film) on a substrate surface;
(d′) a step of performing a heat treatment to crystallize the transparent conductive film (e.g., ITO film);
(a′) a step of forming an Al alloy film having the above-described composition by a sputtering method or the like; and
(b′) a step of performing a heat-treatment that simulates the heat history by CVD process of forming an insulating layer, such as silicon nitride (SiN) film, on the Al alloy film.

The Al alloy film of the present invention is preferably formed by a sputtering method using a sputtering target (hereinafter may be referred to as “target”). This is because a thin film having superior in-plane homogeneity in terms of composition and thickness compared to thin films formed by an ion plating method, an electron beam deposition method, or a vapor deposition method can be easily formed.

In order to form an Al alloy film of the present invention by the sputtering method described above, an Al alloy sputtering target having the same composition as the Al alloy film of the present invention, i.e., 0.01 to 0.5 at. % of Ta and/or Ti, 0.05 to 2.0 at. % of a rare earth element (preferably at least one rare earth element selected from the group consisting of Nd, La, and Gd), and the balance being Al and unavoidable impurities, is preferably used as the target. In this manner, an Al alloy film that substantially satisfies the desired composition can be obtained. The target having the above-described composition is also within the technical scope of the present invention.

The shape of the target may be any shape (rectangular plate shaped, circular plate shaped, doughnut plate shaped, cylindrical, etc.) obtained by processing in accordance with the shape and structure of a sputtering machine.

Examples of the method for producing the target include methods for obtaining the target by producing Al alloy ingots through a melt casting method, a powder sintering method, or a spray forming method, and methods for obtaining the target by producing Al alloy preforms (intermediate products before compact end products) and then compacting preforms by compacting means.

The present invention also includes a thin film transistor (TFT), a reflective film, a reflective anode for organic EL, and a touch panel sensor each including the Al alloy film. The present invention also includes a display device that includes the TFT, the reflective film, the reflective anode for organic EL, or the touch panel sensor. In these devices, the constitutional components other than the Al alloy film featured in the present invention may be appropriately selected from those usually used in the corresponding technical fields as long as the advantages of the present invention are not impaired. For example, the semiconductor layer used in the TFT substrate may be composed of polycrystal silicon or amorphous silicon. The substrate used in the TFT substrate is not particularly limited and examples thereof include a glass substrate and a silicon substrate.

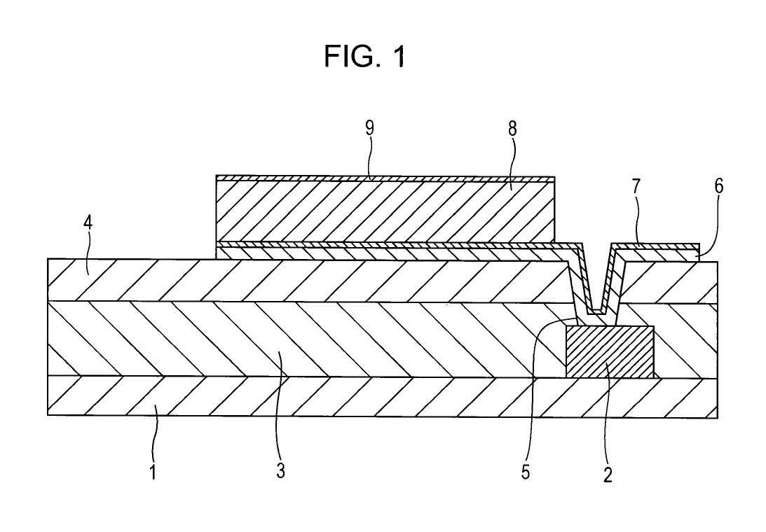

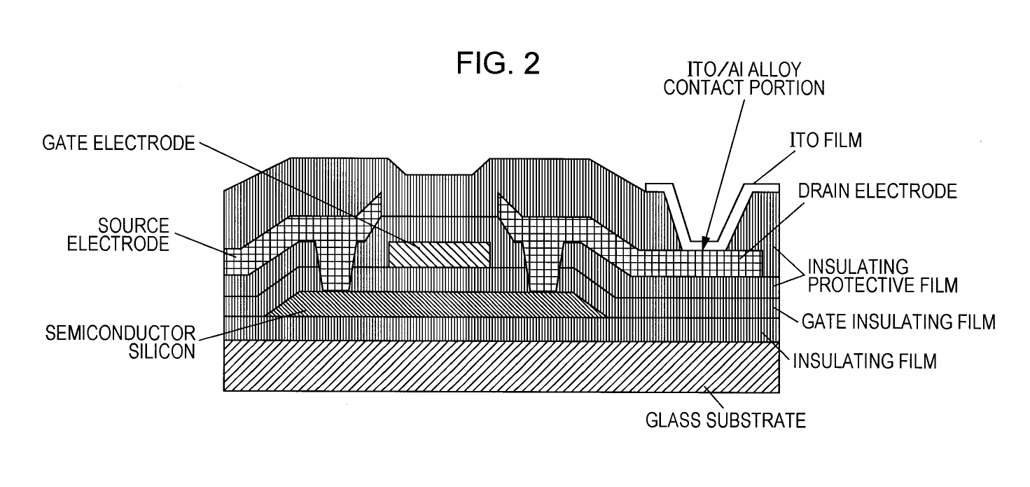

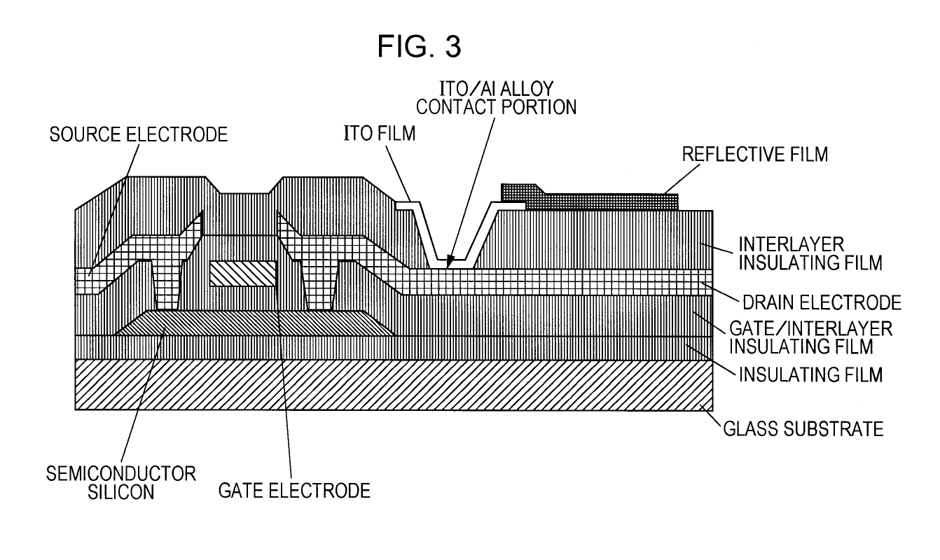

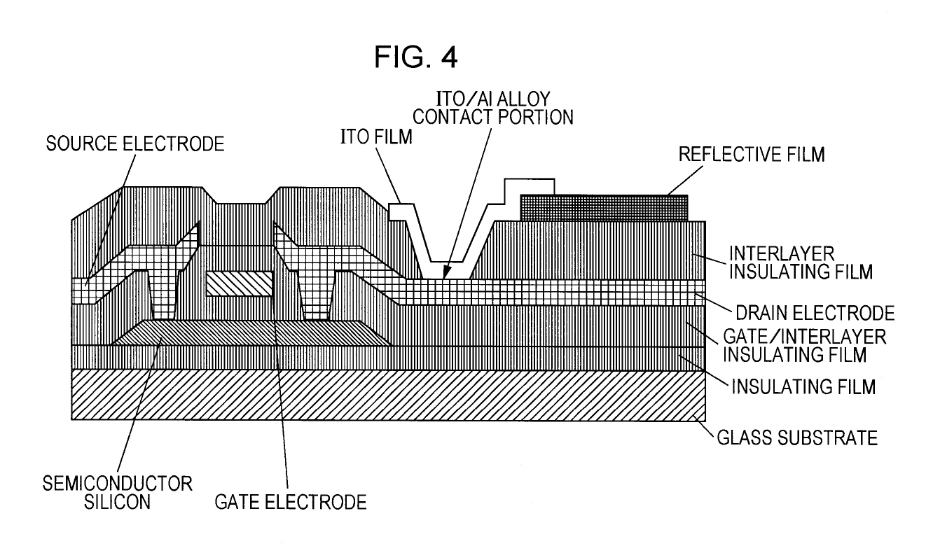

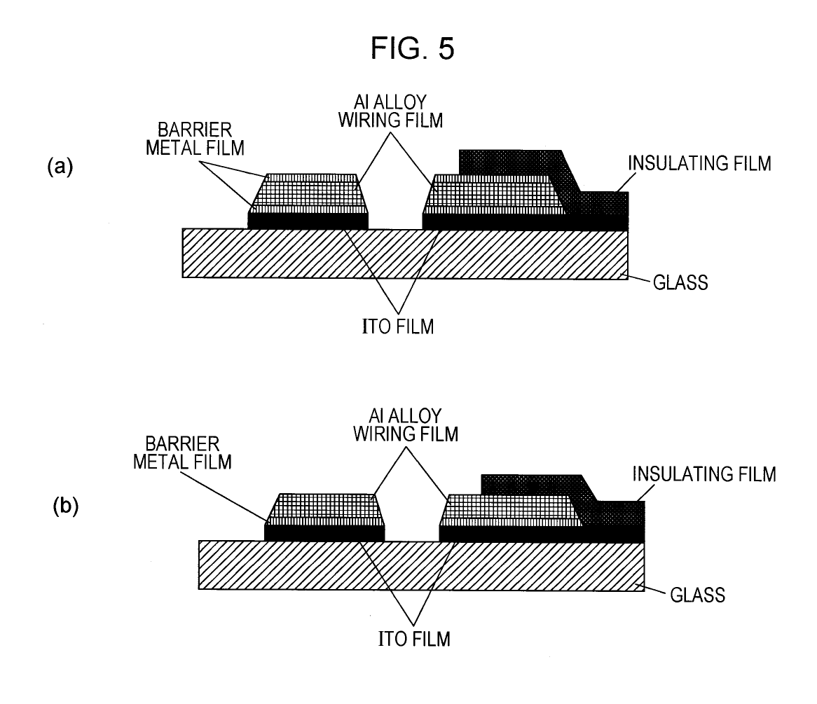

For reference, configurations of the display devices, etc., that include the Al alloy film are shown in FIGS. 1 to 5. In FIG. 1, a configuration of an organic EL display device that includes a reflective anode is shown. More specifically, a TFT 2 and a passivation film 3 are formed on a substrate 1, and a planarizing layer 4 is formed on the TFT 2 and the passivation film 3. A contact hole 5 is formed on the TFT 2 and the source/drain electrodes (not shown) of the TFT 2 are electrically connected to an Al alloy film 6 through the contact hole 5. In FIG. 1, reference numeral 7 denotes an oxide conductive film, 8 denotes an organic emission layer, and 9 denotes a cathode electrode. FIG. 2 shows a configuration of a display device that includes a thin film transistor, in which an ITO film is formed on an Al alloy film that constitutes source and drain electrodes. FIG. 3 shows a configuration of a display device that includes a reflective film, in which an Al alloy reflective film is formed on the ITO film. FIG. 4 also shows a configuration of a display device that includes a reflective film as in FIG. 3. However, contrary to FIG. 3, an ITO film is formed on an Al alloy reflective film. FIGS. 5(a) and (b) show configurations of touch panels each including an Al alloy wiring film on an ITO film. In FIG. 5(a), barrier metal films are disposed on and under the Al alloy wiring film and in FIG. 5(b), a barrier metal layer is disposed under the Al alloy wiring film.

### Examples

The present invention will now be described more specifically by way of examples. However, the scope of the present invention is not limited by these examples and the present invention can naturally be implemented with alternations and modifications within the range that complies with the essence of the present invention described above and below which are included in the technical scope of the present invention.

### Example 1

In this example, a total of four types of samples, namely, a sample in which an Al film was deposited on a substrate (single layer sample), a sample in which an Al film and an ITO film were sequentially formed on a substrate in that order from the substrate side (Al-ITO multilayer sample), and a sample in which an Al film, a refractory metal film (Mo film or Ti film), and an ITO film were sequentially formed on a substrate in that order from the substrate side (Al-refractory metal-ITO multilayer sample), were used and their resistance to corrosion in sodium chloride solution was evaluated. For the Al-ITO multilayer samples, heat resistance was also evaluated.

### (Preparation of Al Film Single Layer Sample)

Al films having compositions shown in Nos. 1 to 33 in Table 1 below (thickness: 300 nm, balance being Al and unavoidable impurities) were each deposited by a DC magnetron sputtering method (conditions were as follows: substrate=glass (“Eagle XG” produced by Corning Incorporated), atmosphere gas=argon, pressure=2 mTorr, substrate temperature=25° C., target size=4 inch, deposition power=260 W/4 inch, deposition time=100 seconds).

The contents of elements in the Al film described above were determined by inductively coupled plasma (ICP) spectrometry.

The Al film was heat-treated at 270° C. retained for 30 minutes so that the heat history that would occur by depositing an insulating film (SiN film) on the Al film was simulated and a single layer sample in which an Al film was disposed on a substrate was thereby obtained. The atmosphere used in this process was an inert atmosphere (N₂ atmosphere) and the average heating rate up to 270° C. was 5° C./min.

For reference, samples were prepared as described above except that a Mo film (No. 34 in Table 1) and a Mo-10.0 at. % Nb alloy film (No. 35 in Table 1, balance: unavoidable impurities) were used instead of the Al film.

(Preparation of an Al-ITO Multilayer Sample or an Al-Refractory Metal-ITO Multilayer Sample, the Order of these Layers being from the Substrate Side)

A multilayer sample (i), i.e., an Al (lower layer)-ITO (upper layer) multilayer sample in which an ITO film was directly formed on a part of an Al film, and a multilayer sample (ii), i.e., an Al (lower layer)-refractory metal (middle layer)-ITO (upper layer) multilayer sample in which an ITO film was formed on a part of an Al film with a refractory metal therebetween, were prepared. In this example, Mo or Ti was used as the refractory metal.

First, a method for preparing an Al (lower layer)-ITO (upper layer) multilayer sample (i) is described. The single layer sample prepared as described above was used. A mask pattern composed of a photosensitive resin resist was formed by photolithography on the surface of the Al film in order to form an ITO film having a width of 10 μm at 10 μm intervals.

An ITO film (thickness: 200 nm) was deposited thereon under the following conditions. That is, a 4 inch ITO target was used and an ITO film was deposited by a DC magnetron sputtering method (atmosphere gas=mixed gas of 99.2% argon and 0.8% oxygen, pressure=0.8 mTorr, substrate temperature=25° C., target size=4 inch, deposition power=150 W/4 inch, deposition time=33 seconds).

After deposition of the film, the mask pattern composed of the photosensitive resin was dissolved in an acetone solution and at the same time the ITO film on the resin was removed by lift-off. As a result, an ITO film having a width of 10 μm at 10 μm intervals was formed.

Then a temperature of 250° C. was retained for 15 minutes in an inert atmosphere (N₂ atmosphere) to crystallize the ITO film. As a result, the multilayer sample (i) in which an Al film (lower layer) and an ITO film (upper layer) were sequentially deposited on the substrate was obtained. The average heating rate up to 250° C. was 5° C./min.

An Al (lower layer)-refractory metal (middle layer)-ITO (upper layer) multilayer sample (ii) was prepared by, after forming the Al film by the method for preparing the multilayer sample (i) described above, photographically forming a mask pattern composed of a photosensitive resin resist on the surface of the Al film in order to form a Mo or Ti film having a width of 12 μm and 8 μm intervals. Then, a Mo film (thickness: 50 nm) or a Ti film (thickness: 50 nm) was deposited thereon by a DC magnetron sputtering method (atmosphere gas=argon, pressure=2 mTorr, substrate temperature=25° C., target size=4 inch, deposition power=260 W/4 inch), and after the deposition, the mask pattern composed of the photosensitive rein was dissolved in an acetone solution and at the same time the Mo film or the Ti film on the resin was removed by lift-off. As a result, a Mo or Ti film having a width of 12 μm at 8 μm intervals was formed. A multilayer sample (ii) was prepared as in (i) with an ITO film (thickness: 200 nm).

For reference, multilayer sample (i) or (ii) was prepared as described above except that a Mo film (No. 34 in Table 1) and a Mo-10.0 at. % Nb alloy film (No. 35 in Table 1, balance: unavoidable impurities) were used instead of the Al film.

Each of the samples obtained as above was subjected to a corrosion resistance test in sodium chloride solution as below and the heat resistance was evaluated according to the following method.

### <Immersion Test in Aqueous Sodium Chloride Solution>

Each sample was subjected to a test of immersing the sample in a 1% aqueous sodium chloride solution (25° C.) for 2 hours and three areas of observation of the sample surface (surface of the Al film for single layer samples and the surface of the Al film on which no ITO film was formed for multilayer samples) after the immersion test were observed with an optical microscope at a magnification of 1000 (observation range: about 8600 μm²). Regarding the evaluation of the corrosion resistance in sodium chloride solution, samples in which the fraction of the discolored area generated by corrosion was 10% or less relative to the total area of the Al film surface were rated as good and samples in which this fraction was more than 10% were rated poor. The results are shown in Table 1.

### <Heat Resistance Test>

The density of hillocks formed on the Al film surface after the thermal crystallization treatment of the ITO film was measured for the multilayer samples described above. In particular, the Al film surface on which no ITO film was formed was observed with an optical microscope (observed positions: three arbitrarily selected positions, area of view: 120×160 μm) and the number of hillocks having a diameter of 0.1 μm or more was counted (the diameter here means the longest portion of the hillock). Samples with a hillock density less than 1×10⁹ were evaluated as good and samples with a hillock density of 1×10⁹ or more were evaluated as poor. The results are also shown in Table 1 (Heat resistance).

TABLE 1

| | | | | | | Heat |
|---|---|---|---|---|---|---|
| | | Immersion test in aqueous sodium chloride solution | | | | resistance |
| | | Single | Multilayer sample | | | Multilayer |
| | | layer | | Al (lower) - | Al (lower) - | sample |
| | Composition | sample | Al (lower) - | Mo (middle) - | Ti (middle) | Al (lower) - |
| No | (at. %) | Al | ITO (upper) | ITO (upper) | ITO (upper) | ITO (upper) |
| 1 | Al—0.05 Nd—0.01 Ta | Good | Good | Good | Good | Good |
| 2 | Al—0.1 Nd—0.01 Ta | Good | Good | Good | Good | Good |
| 3 | Al—0.3 Nd—0.01 Ta | Good | Good | Good | Good | Good |
| 4 | Al—0.05 Nd—0.05 Ta | Good | Good | Good | Good | Good |
| 5 | Al—0.1 Nd—0.05 Ta | Good | Good | Good | Good | Good |
| 6 | Al—0.3 Nd—0.05 Ta | Good | Good | Good | Good | Good |
| 7 | Al—0.3 Nd—0.1 Ta | Good | Good | Good | Good | Good |
| 8 | Al—0.05 Nd—0.15 Ta | Good | Good | Good | Good | Good |
| 9 | Al—0.1 Nd—0.15 Ta | Good | Good | Good | Good | Good |
| 10 | Al—0.2 Nd—0.15 Ta | Good | Good | Good | Good | Good |
| 11 | Al—0.3 Nd—0.15 Ta | Good | Good | Good | Good | Good |
| 12 | Al—0.4 Nd—0.15 Ta | Good | Good | Good | Good | Good |
| 13 | Al—0.05 Nd—0.3 Ta | Good | Good | Good | Good | Good |
| 14 | Al—0.1 Nd—0.3 Ta | Good | Good | Good | Good | Good |
| 15 | Al—0.2 Nd—0.3 Ta | Good | Good | Good | Good | Good |
| 16 | Al—0.3 Nd—0.3 Ta | Good | Good | Good | Good | Good |
| 17 | Al—0.4 Nd—0.3 Ta | Good | Good | Good | Good | Good |
| 18 | Al—0.3 La—0.01 Ta | Good | Good | Good | Good | Good |
| 19 | Al—0.3 La—0.15 Ta | Good | Good | Good | Good | Good |
| 20 | Al—0.3 La—0.3 Ta | Good | Good | Good | Good | Good |
| 21 | Al—0.3 Gd—0.01 Ta | Good | Good | Good | Good | Good |
| 22 | Al—0.3 Gd—0.15 Ta | Good | Good | Good | Good | Good |
| 23 | Al—0.3 Gd—0.3 Ta | Good | Good | Good | Good | Good |
| 24 | Al—0.3 Nd—0.01 Ti | Good | Good | Good | Good | Good |
| 25 | Al—0.3 Nd—0.05 Ti | Good | Good | Good | Good | Good |
| 26 | Al—0.3 Nd—0.1 Ti | Good | Good | Good | Good | Good |
| 27 | Al—0.3 Nd—0.15 Ti | Good | Good | Good | Good | Good |
| 28 | Al—0.3 Nd—0.3 Ti | Good | Good | Good | Good | Good |
| 29 | Al—0.3 Nd | Poor | Poor | Poor | Poor | Good |
| 30 | Al—2.0 Nd | Poor | Poor | Poor | Poor | Good |
| 31 | Al—0.3 Ta | Good | Good | Good | Good | Poor |
| 32 | Al—0.3 Ti | Good | Good | Good | Good | Poor |
| 33 | Al | Poor | Poor | Poor | Poor | Poor |
| 34 | Mo | Poor | Poor | Poor | Poor | Good |
| 35 | Mo—10.0 Nb | Good | Poor | Poor | Poor | Good |

Nos. 1 to 28 in Table 1 are examples that each use the Al alloy film satisfying the requirements of the present invention. They exhibited high resistance to corrosion in sodium chloride solution and high heat resistance.

In contrast, Nos. 29 and 30 are examples in which Ta and/or Ti defined in the present invention is not contained. These examples exhibited high heat resistance due to incorporation of particular amounts of rare earth elements; however, corrosion caused by sodium chloride was observed and satisfactory resistance to corrosion in sodium chloride solution was not achieved.

Nos. 31 and 32 are examples that do not contain rare earth elements. Since they contain a particular amount of Ta/Ti, corrosion caused by sodium chloride did not occur and high resistance to corrosion in sodium chloride solution was exhibited; however, the heat resistance was low.

No. 33 is an example in which a pure Al film not containing any alloy element was used. In this example, corrosion due to sodium chloride occurred and the heat resistance was also low.

No. 34 is an example in which Mo was used. Although the heat resistance was high, corrosion occurred due to sodium chloride.

No. 35 is an example in which Mo-10.0 at. % Nb, a mixture of Mo and an anti-corrosion element Nb, was used. Corrosion due to sodium chloride was suppressed in the single layer sample, but corrosion occurred in multilayer samples. This means that this example is not sufficient for use in display devices. The heat resistance of the multilayer samples was satisfactory.

### Example 2

In this example, the Al films of Nos. 1 to 33 shown in Table 1 used in Example 1 described above were used and a multilayer sample (iii), i.e., a multilayer sample (ITO-Al multilayer sample) in which an ITO film (lower layer) and an Al film (upper layer) were sequentially formed on a substrate in that order from the substrate side, a multilayer sample (iv), i.e., a multilayer sample (ITO-refractory metal-Al multilayer sample) in which an ITO film (lower layer), a refractory metal film (middle layer, Mo or Ti film), and an Al film (upper layer) were sequentially formed on a substrate in that order from the substrate side, and a multilayer sample (v), i.e., a multilayer sample (ITO-Al-refractory metal multilayer sample) in which an ITO film (lower layer), an Al film (middle layer), and a refractory metal film (upper layer, Mo or Ti film) were sequentially formed on a substrate in that order form the substrate side, were prepared. The resistance to corrosion in sodium chloride solution was evaluated as in Example 1.

In particular, an ITO film (thickness: 200 nm) was formed under the following conditions. That is, an ITO film was deposited by using a 4 inch ITO target by a DC magnetron sputtering method (substrate=glass (“Eagle XG” produced by Corning Incorporated), atmosphere gas=mixed gas of 99.2% argon and 0.8% oxygen, pressure=0.8 mTorr, substrate temperature=25° C., target size=4 inch, deposition power=150 W/4 inch, deposition time=33 seconds).

Subsequently, a temperature of 250° C. was retained for 15 minutes in an inert atmosphere (N₂ atmosphere) to crystallize the ITO film. The atmosphere during this process was inert atmosphere (N₂ atmosphere) and the average heating rate up to 250° C. was 5° C./min.

In order to prepare the multilayer sample (iii) above, a mask pattern composed of a photosensitive resin resist was photographically formed in order to form an Al film (10 μm in width) having compositions shown in Table 2 at 10 μm intervals.

Al films (thickness: 300 nm) having compositions shown in Table 2 were deposited thereon by a DC magnetron sputtering method (atmosphere gas=argon, pressure=2 mTorr, substrate temperature=25° C., target size=4 inch, deposition power=260 W/4 inch, deposition time=117 seconds).

The contents of the elements in the Al films were determined by inductively coupled plasma (ICP) spectroscopy.

Each Al film was heat-treated at 270° C. retained for 30 minutes so that the heat history that would occur by depositing an insulating film (SiN film) on the Al film was simulated and an ITO (lower layer)-Al (upper layer) multilayer layer sample (iii) in which an ITO film and an Al alloy film or a Mo alloy film were deposited on the substrate was obtained. The atmosphere used in this process was an inert atmosphere (N₂ atmosphere) and the average heating rate up to 270° C. was 5° C./min.

In preparing the multilayer sample (iv) described above, in order to prepare an ITO (lower layer)-refractory metal (middle layer)-Al (upper layer) multilayer sample in which the Al film was deposited after the refractory metal film (Mo or Ti) was formed on the ITO film and in order to deposit a refractory metal film (Mo or Ti) (12 μm in width) on the ITO film surface at 8 μm intervals, a mask pattern composed of a photosensitive resin resist was photographically formed. After the refractory metal film (Mo or Ti) (thickness: 50 nm) was deposited thereon by a DC magnetron sputtering method (atmosphere gas=argon, pressure=2 mTorr, substrate temperature=25° C., target size=4 inch, deposition power=260 W/4 inch), the mask pattern composed of the photosensitive resin was dissolved in an acetone solution and at the same time the refractory metal film (Mo or Ti) on the resin was removed by lift-off. As a result, a refractory metal film (Mo or Ti) having a width of 12 μm was formed at 8 μm intervals. Next, a mask pattern composed of a photosensitive resin resist was photographically formed on the surface of the refractory metal film (Mo or Ti) in order to form Al films (10 μm in width) having compositions shown in Table 2 below at 10 μm intervals. Then Al films (thickness: 300 nm) having compositions shown in Table 2 were deposited thereon by a DC magnetron sputtering method (atmosphere gas=argon, pressure=2 mTorr, substrate temperature=25° C., target size=4 inch, deposition power=260 W/4 inch, deposition time=117 seconds). The mask pattern composed of the photosensitive resin was dissolved in an acetone solution and at the same time the Al films having compositions shown in Table 2 on the resin were removed by lift-off. As a result, multilayer samples (iv) in which the Al films having the composition shown in Table 2 and a width of 10 μm were formed at 10 μm intervals.

In preparing the multilayer sample (v) above, in order to prepare an ITO (upper layer)-Al (middle)-refractory metal (upper layer) multilayer sample in which the refractory metal film (Mo or Ti) was deposited after forming the Al film on the ITO film, a mask pattern composed of a photosensitive resin resist was photographically formed in order to form an Al film (12 μm in width) having a composition shown in Table 2 on the ITO film surface at 8 μm intervals. After the Al film (thickness: 300 nm) having the composition shown in Table 2 was deposited thereon by a DC magnetron sputtering method (atmosphere gas=argon, pressure=2 mTorr, substrate temperature=25° C., target size=4 inch, deposition power=260 W/4 inch), the mask pattern composed of the photosensitive resin was dissolved in an acetone solution and at the same time the Al film having the composition shown in Table 2 on the resin was removed by lift-off. As a result, an Al film having the composition shown in Table 2 and a width of 12 μm was formed at 8 μm intervals. Next, a mask pattern composed of a photosensitive resin resist was photographically formed on the surface of the Al film having the composition shown in Table 2 in order to deposit a refractory metal film (Mo or Ti film) (10 μm in width) at 10 μm intervals. Then a refractory metal film (Mo or Ti film) (thickness: 300 nm) was deposited thereon by a DC magnetron sputtering method (atmosphere gas=argon, pressure=2 mTorr, substrate temperature=25° C., target size=4 inch, deposition power=260 W/4 inch). The mask pattern composed of the photosensitive resin was dissolved in an acetone solution and at the same time the refractory metal film (Mo film or Ti film) on the resin were removed by lift-off. As a result, a multilayer sample (v) in which the refractory metal film (Mo film or Ti film) having a width of 10 μm was formed at 10 μm intervals was obtained.

For reference, multilayer samples (iii) to (v) were prepared as described above except that Mo (No. 34 in Table 2) and Mo-10.0 at. % Nb alloy films (No. 35 in Table 2, balance: unavoidable impurities) were used instead of the Al film.

The resistance to corrosion in sodium chloride solution was evaluated as in Example 1 for each multilayer sample obtained as such. The results are shown in Table 2.

TABLE 2

| | | Immersion test in aqueous sodium chloride solution | | | | |
|---|---|---|---|---|---|---|
| | | Multilayer sample | | | | |
| | | | ITO (lower) - | ITO (lower) - | ITO (lower) - | ITO (lower) - |
| | Composition | ITO (lower) - | Mo (middle) - | Ti (middle) - | Al (middle) - | Al (middle) - |
| No. | (at. %) | Al (upper) | Al (upper) | Al (upper) | Mo (upper) | Ti (upper) |
| 1 | Al—0.05 Nd—0.01 Ta | Good | Good | Good | Good | Good |
| 2 | Al—0.1 Nd—0.01 Ta | Good | Good | Good | Good | Good |
| 3 | Al—0.3 Nd—0.01 Ta | Good | Good | Good | Good | Good |
| 4 | Al—0.05 Nd—0.05 Ta | Good | Good | Good | Good | Good |
| 5 | Al—0.1 Nd—0.05 Ta | Good | Good | Good | Good | Good |
| 6 | Al—0.3 Nd—0.05 Ta | Good | Good | Good | Good | Good |
| 7 | Al—0.3 Nd—0.1 Ta | Good | Good | Good | Good | Good |
| 8 | Al—0.05 Nd—0.15 Ta | Good | Good | Good | Good | Good |
| 9 | Al—0.1 Nd—0.15 Ta | Good | Good | Good | Good | Good |
| 10 | Al—0.2 Nd—0.15 Ta | Good | Good | Good | Good | Good |
| 11 | Al—0.3 Nd—0.15 Ta | Good | Good | Good | Good | Good |
| 12 | Al—0.4 Nd—0.15 Ta | Good | Good | Good | Good | Good |
| 13 | Al—0.05 Nd—0.3 Ta | Good | Good | Good | Good | Good |
| 14 | Al—0.1 Nd—0.3 Ta | Good | Good | Good | Good | Good |
| 15 | Al—0.2 Nd—0.3 Ta | Good | Good | Good | Good | Good |
| 16 | Al—0.3 Nd—0.3 Ta | Good | Good | Good | Good | Good |
| 17 | Al—0.4 Nd—0.3 Ta | Good | Good | Good | Good | Good |
| 18 | Al—0.3 La—0.01 Ta | Good | Good | Good | Good | Good |
| 19 | Al—0.3 La—0.15 Ta | Good | Good | Good | Good | Good |
| 20 | Al—0.3 La—0.3 Ta | Good | Good | Good | Good | Good |
| 21 | Al—0.3 Gd—0.01 Ta | Good | Good | Good | Good | Good |
| 22 | Al—0.3 Gd—0.15 Ta | Good | Good | Good | Good | Good |
| 23 | Al—0.3 Gd—0.3 Ta | Good | Good | Good | Good | Good |
| 24 | Al—0.3 Nd—0.01 Ti | Good | Good | Good | Good | Good |
| 25 | Al—0.3 Nd—0.05 Ti | Good | Good | Good | Good | Good |
| 26 | Al—0.3 Nd—0.1 Ti | Good | Good | Good | Good | Good |
| 27 | Al—0.3 Nd—0.15 Ti | Good | Good | Good | Good | Good |
| 28 | Al—0.3 Nd—0.3 Ti | Good | Good | Good | Good | Good |
| 29 | Al—0.3 Nd | Poor | Poor | Poor | Poor | Poor |
| 30 | Al—2.0 Nd | Poor | Poor | Poor | Poor | Poor |
| 31 | Al—0.3 Ta | Good | Good | Good | Good | Good |
| 32 | Al—0.3 Ti | Good | Good | Good | Good | Good |
| 33 | Al | Poor | Poor | Poor | Poor | Poor |
| 34 | Mo | Poor | Poor | Poor | Poor | Poor |
| 35 | Mo—10.0 Nb | Poor | Poor | Poor | Poor | Poor |

Table 2 shows that the same results as those using the multilayer samples of Table 1 are obtained. In other words, in Nos. 1 to 28 of Table 1 in which the Al alloy film of the present invention is used, high resistance to corrosion in sodium chloride solution was exhibited in all of the multilayer sample (iii) in which the Al alloy film was directly formed on the ITO film, the multilayer sample (iv) in which the refractory metal and the Al alloy film were sequentially formed on the ITO film, and the multilayer sample (v) in which the Al alloy film and the refractory metal film (Mo film or Ti film) were sequentially formed on the ITO film. In contrast, the corrosion resistance deteriorated in Nos. 29 and 30 in which an Al alloy film that does not satisfy the composition defined in the present invention was used, No. 34 in which the Mo film was used instead of the Al film alloy film, and No. 35 in which the Mo alloy film was used.

### Example 3

In this example, the Al films of Nos. 1 to 33 in Table 1 used in Example 1 described above were used to prepare multilayer samples (Al-ITO) each in which an Al film and an ITO film were sequentially deposited on a substrate, and the ITO pinhole corrosion resistance (ITO pinhole corrosion density reducing effect) was investigated.

In particular, the Al films (thickness=300 nm, balance: Al and unavoidable impurities) having compositions shown in Table 3 below were deposited by a DC magnetron sputtering method (substrate=glass (“Eagle XG” produced by Corning Incorporate), atmosphere gas=argon, pressure=2 mTorr, substrate temperature=25° C., target size=4 inch, deposition power=260 W/4 inch, deposition time=100 seconds).

The contents of the elements in the Al films were determined by inductively coupled plasma (ICP) spectroscopy.

Each Al film was heat-treated at 270° C. retained for 30 minutes so that the heat history that would occur by depositing an insulating film (SiN film) on the Al film was simulated. The atmosphere used in this process was an inert atmosphere (N₂ atmosphere) and the average heating rate up to 270° C. was 5° C./min.

An ITO film was formed under the following conditions on the surface of each heat-treated Al film. That is, an ITO film was formed by using a 4 inch ITO target by a DC magnetron sputtering method (atmosphere gas=mixed gas of 99.2% argon and 0.8% oxygen, pressure=0.8 mTorr, substrate temperature=25° C., target size=4 inch, deposition power=150 W/4 inch, deposition time=33 seconds).

After deposition, a temperature of 250° C. was retained for 15 minutes in an inert atmosphere (N₂ atmosphere) to crystallize the ITO film. The atmosphere during this process was an inert atmosphere (N₂ atmosphere) and the average heating rate up to 250° C. was 5° C./min.

Each sample was subjected to a pinhole corrosion test by the following method to investigate the ITO pinhole corrosion density after testing and the heat resistance was evaluated by the aforementioned method.

### <Pinhole Corrosion Test>

Each sample was subjected to a pinhole corrosion test of exposing the sample to a 60° C.×90% RH humid environment for 500 hours by simulating the conditions of the transportation and storage described above. The surface after testing was observed with a ×1000 optical microscope (observation range: about 8600 μm²), the number of black dots existing in the range was counted to calculate the number of black dots per mm² (average of 10 areas of observation arbitrary selected), and the black dot density after testing (ITO pinhole corrosion density) was determined. The results are shown in Table 3.

The cases where black dot density was 40 dots/mm² or less were evaluated as the state in which generation of pinholes is suppressed in the ITO film and the pinhole corrosion is sufficiently suppressed. The cases where black dot density was over 40 dots/mm² were evaluated as the state in which a large number of pinholes are generated in the ITO film and the pinhole corrosion occurs in the corrosion test.

TABLE 3

| | Composition | Pinhole corrosion density | Heat |
|---|---|---|---|
| No. | (at. %) | (pinholes/mm²) | resistance |
| 1 | Al-0.05 Nd-0.01 Ta | 25 | Good |
| 2 | Al-0.1 Nd-0.01 Ta | 23 | Good |
| 3 | Al-0.3 Nd-0.01 Ta | 22 | Good |
| 4 | Al-0.05 Nd-0.05 Ta | 17 | Good |
| 5 | Al-0.1 Nd-0.05 Ta | 18 | Good |
| 6 | Al-0.3 Nd-0.05 Ta | 16 | Good |
| 7 | Al-0.3 Nd-0.1 Ta | 16 | Good |
| 8 | Al-0.05 Nd-0.15 Ta | 9 | Good |
| 9 | Al-0.1 Nd-0.15 Ta | 8 | Good |
| 10 | Al-0.2 Nd-0.15 Ta | 7 | Good |
| 11 | Al-0.3 Nd-0.15 Ta | 8 | Good |
| 12 | Al-0.4 Nd-0.15 Ta | 6 | Good |
| 13 | Al-0.05 Nd-0.3 Ta | 5 | Good |
| 14 | Al-0.1 Nd-0.3 Ta | 5 | Good |
| 15 | Al-0.2 Nd-0.3 Ta | 6 | Good |
| 16 | Al-0.3 Nd-0.3 Ta | 4 | Good |
| 17 | A1-0.4 Nd-0.3 Ta | 5 | Good |
| 18 | Al-0.3 La-0.01 Ta | 34 | Good |
| 19 | Al-0.3 La-0.15 Ta | 9 | Good |
| 20 | Al-0.3 La-0.3 Ta | 7 | Good |
| 21 | Al-0.3 Gd-0.01 Ta | 34 | Good |
| 22 | Al-0.3 Gd-0.15 Ta | 8 | Good |
| 23 | Al-0.3 Gd-0.3 Ta | 4 | Good |
| 24 | Al-0.3 Nd-0.01 Ti | 38 | Good |
| 25 | Al-0.3 Nd-0.05 Ti | 34 | Good |
| 26 | Al-0.3 Nd-0.1 Ti | 30 | Good |
| 27 | Al-0.3 Nd-0.15 Ti | 28 | Good |
| 28 | Al-0.3 Nd-0.3 Ti | 15 | Good |
| 29 | Al-0.3 Nd | 1600 | Good |
| 30 | Al-2.0 Nd | 1300 | Good |
| 31 | Al-0.3 Ta | 7 | Poor |
| 32 | Al-0.3 Ti | 17 | Poor |
| 33 | Al | 480 | Poor |

The following can be learned from Table 3.

Nos. 1 to 28 in Table 3 are examples that use Al alloy films that satisfy the requirements of the present invention. Generation of pinhole corrosion is sufficiently suppressed in the pinhole corrosion test, and the heat resistance was satisfactory.

In contrast, Nos. 29 and 30 are examples that do not contain Ta and/or Ti and although the heat resistance is high due to incorporation of a particular amount of a rare earth element, the ITO pinhole corrosion density could not be decreased to a desired level.

In contrast, Nos. 31 and 32 are examples that do not contain rare earth elements. Although generation of pinhole corrosion was sufficiently suppressed due to incorporation of a particular amount of Ta/Ti, the heat resistance was low.

No. 33 is an example that used a pure Al film to which no alloy elements were added. The pinhole corrosion density was high and the heat resistance was low.

While the present invention has been described with reference to exemplary embodiments, it is obvious for persons skilled in the art that various modifications and alternations are possible without departing from the spirit and scope of the present invention.

This application claims the benefit of Japanese Patent Application No. 2010-222005 filed Sep. 30, 2010 and No. 2011-127711 filed Jun. 7, 2011, which are hereby incorporated by reference herein in their entirety.

### INDUSTRIAL APPLICABILITY

According to the present invention, a high-performance Al alloy film that does not corrode even when the film has not been subjected to a process of application and removal of an anticorrosion coating solution as in the related art and that exhibits excellent heat resistance and corrosion resistance, and a wiring structure, a thin film transistor, a reflective film, a reflective anode for organic EL, a touch panel sensor, and a display device that each include the Al alloy film can be produced at low cost. A sputtering target of the present invention is suitable for use in production of the Al alloy film.

1. An Al alloy film, comprising:
from 0.01 to 0.5 at. % of Ta, Ti, or a mixture thereof; and
from 0.05 to 2.0 at. % of a rare earth element.

2. The Al alloy film according to claim 1, wherein the rare earth element is at least one element selected from the group consisting of Nd, La, and Gd.

3. The Al alloy film according to claim 1, wherein when the Al alloy film is immersed in a 1% aqueous sodium chloride solution at 25° C. for 2 hours and a surface of the Al alloy film is observed with an optical microscope at a magnification of 1000, a fraction of a corroded area in an Al alloy film surface relative to a total area of the Al alloy film surface is suppressed to 10% or less.

4. A wiring structure, comprising:
a substrate;
the Al alloy film according to claim 1; and
a transparent conductive film,
wherein from the substrate side,
the Al alloy film and the transparent conductive film are formed in that order, or
the transparent conductive film and the Al alloy film are formed in that order.

5. The wiring structure according to claim 4, wherein the Al alloy film is directly connected to the transparent conductive film.

6. The wiring structure according to claim 4,
wherein the Al alloy film and the transparent conductive film are formed in that order from the substrate side, and
wherein when an Al-transparent conductive film multilayer sample in which the transparent conductive film is formed on a part of the Al alloy film either directly or with a refractory metal film therebetween is immersed in a 1% aqueous sodium chloride solution at 25° C. for 2 hours and an Al alloy film surface on which the transparent conductive film is not formed is observed with an optical microscope at a magnification of 1000, a fraction of a corroded area in an Al alloy film surface relative to a total area of the Al alloy film surface on which the transparent conductive film is not formed is suppressed to 10% or less.

7. The wiring structure according to claim 4,
wherein the transparent conductive film and the Al alloy film are formed in that order from the substrate side, and
wherein when a transparent conductive film-Al multilayer sample in which the Al alloy film is formed on the transparent conductive film either directly or with a refractory metal film therebetween or in which the Al alloy film is formed on the transparent conductive film and a refractory metal film is formed on a part of the Al alloy film is immersed in a 1% aqueous sodium chloride solution at 25° C. for 2 hours and a surface of the Al alloy film is observed with an optical microscope at a magnification of 1000, a fraction of a corroded area in an Al alloy film surface relative to a total area of the Al alloy film surface is suppressed to 10% or less.

8. The wiring structure according to claim 4, wherein the Al alloy film and the transparent conductive film are formed in that order from a substrate side, and
wherein when an Al-transparent conductive film multilayer sample in which the transparent conductive film is directly formed on the Al alloy film is exposed to a humid environment at a temperature of 60° C. and a relative humidity of 90% for 500 hours, a density of pinhole corrosion formed through pinholes in the transparent conductive film is 40 pinholes/mm² or less in an area of observation with an optical microscope at a magnification of 1000.

9. The wiring structure according to claim 4, wherein the transparent conductive film comprises ITO or IZO.

10. The wiring structure according to claim 4, wherein a thickness of the transparent conductive film is from 20 to 120 nm.

11. A thin film transistor, comprising the wiring structure according to claim 4.

12. A reflective film, comprising the wiring structure according to claim 4.

13. A reflective anode for organic EL, comprising the wiring structure according to claim 4.

14. A touch panel sensor, comprising the Al alloy film according to claim 1.

15. A display device, comprising the thin film transistor according to claim 11.

16. A display device, comprising the reflective film according to claim 12.

17. A display device, comprising the reflective anode for organic EL according to claim 13.

18. A display device, comprising the touch panel sensor according to claim 14.

19. A sputtering target, comprising:
Al;
from 0.01 to 0.5 at. % of Ta, Ti, or a mixture thereof; and
from 0.05 to 2.0 at. % of a rare earth element.

20. The sputtering target according to claim 19, wherein the rare earth element is at least one element selected from the group consisting of Nd, La, and Gd.
